(19) United States
(12) Patent Application Publication
(10) Pub. No.: US 2013/0125983 A1
(43) Pub. Date: May 23, 2013

(54) Imprinted Dielectric Structures

(71) Applicant: Dirk N. Weiss, San Jose, CA (US)

(72) Inventor: Dirk N. Weiss, San Jose, CA (US)

(73) Assignee: INTEGRATED PHOTOVOLTAIC, INC., San Jose, CA (US)

(21) Appl. No.: 13/300,046

(22) Filed: Nov. 18, 2011

(51) Int. Cl. H01L 31/0232; H01L 31/18

(52) U.S. Cl. 136/259; 438/57; 257/E31.124

(57) ABSTRACT

A method for manufacturing a photovoltaic device comprises the steps choosing a substrate with a conductive layer; depositing a non-conductive layer; imprinting a structure comprising features into the non-conductive layer; and depositing an active layer operable in the photovoltaic device; wherein the active layer is in electrical contact with the conductive layer through a feature in the imprinted layer.

### CROSS-REFERENCE TO RELATED APPLICATIONS

This application is related in part to U.S. application Ser. Nos. 12/074,651, 12/720,153, 12/749,160, 12/789,357, 12/860,048, 12/860,088, 12/950,725, 12/860,088, 13/010,700, 13/019,965, 13/073,884, 13/077,870, 13/104,881, 13/214,158, 13/268,041, 13/272,073, 13/273,175, 13/234,316 and U.S. Pat. No. 7,789,331, all owned by the same assignee and all incorporated by reference in their entirety herein. Additional technical explanation and background is cited in the referenced material.

### BACKGROUND OF THE INVENTION.

1. Field of the Invention

The invention discloses a method and structure comprising a via through a dielectric layer formed by imprinting in a solar cell.

2. Description of Related Art

Crystalline silicon has an indirect electronic band gap. The absorption length for light in silicon therefore increases with increasing wavelength. As a consequence, the total absorption of sunlight in a silicon solar cell decreases with decreasing silicon thickness. While a thick (180 μm) silicon solar cell absorbs 90% of all available photons in sunlight with energy higher than the band gap energy of silicon, and a 50 μm thick silicon layer still absorbs 82% of photons, a 10 μm thick silicon layer absorbs only 65% of all available photons (source: our own model calculations).

The associated loss in short-circuit current and photovoltaic conversion efficiency scales with the photon absorption, which is shown in FIG. 1 for a model calculation in which only photon absorption is varied with silicon layer thickness. As a consequence, very thin crystalline silicon solar cells will require strategies for ‘light trapping’ in order to ‘recycle’ non-absorbed photons in the solar cell. This is achieved by changing the angle of a light ray that either enters the cell or is reflected at the back side of the absorber layer. If the new angle of the light ray is sufficiently shallow, the light ray can be trapped by total internal reflection.

Related art is found in U.S. Pat. Nos. 5,485,038, 5,772,905, U.S. Pat. No. 7,351,660, WO/1992/014270, WO/2007/004128, PCT/US2008/004096, U.S. 2007/0098959. Related art is found in publications by the author; D. N. Weiss, H.-C. Yuan, B. G. Lee, H. M. Branz, S. T. Meyers, A. Grenville and D. A. Keszler, Journal of Vacuum Science and Technology B 28, C6M98 (2010); D. N. Weiss, S. T. Meyers and D. A. Keszler, Journal of Vacuum Science & Technology B 28 (4), 823-828 (2010); D. A. Richmond, Q. Zhang, G. Cao and D. N. Weiss, J. Vac. Sci. Technol. B 92 (2), 021603 (2011). Related art cited herein is incorporated in its entirety herein by reference.

### SUMMARY OF THE INVENTION

The instant invention discloses a layer of solar-grade silicon that is deposited, optionally, plasma-sprayed, onto a low-cost substrate and optionally, recrystallized, optionally by a technique disclosed in U.S. 13/010,700 and U.S. 13/234,316. To reduce solar cell active layers of 50 μm thick layers to 10 μm layers requires light trapping to achieve high efficiencies. In some embodiments a device architecture enables light trapping through photonic structures, smaller or larger than the wavelength range of sunlight that are produced by imprinting, optionally, nano-imprinting, embossing, hot embossing, UV embossing, of a curable compliant precursor material.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 shows solar cell efficiency as a function of silicon active layer thickness.

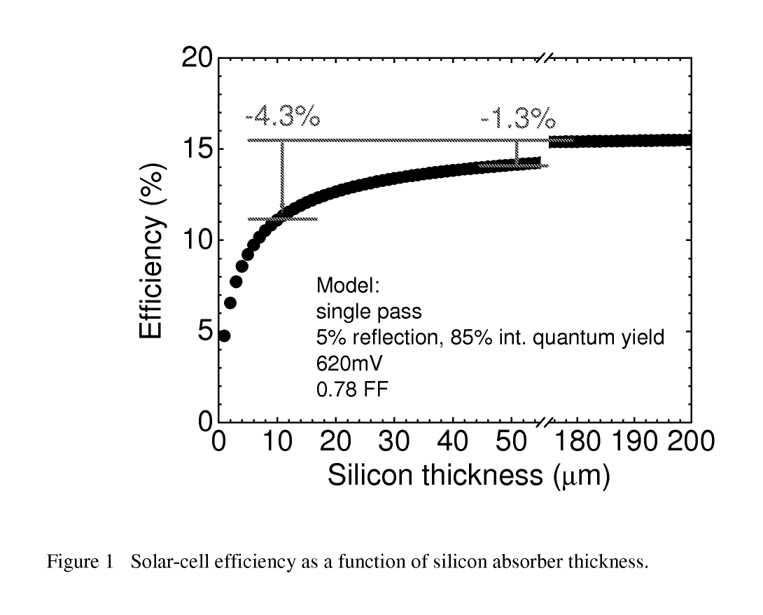

FIG. 2 is a schematic view for some embodiments.

FIG. 3 is a schematic view for some embodiments of an imprinting process.

### DETAILED DESCRIPTION OF THE PREFERRED EMBODIMENTS

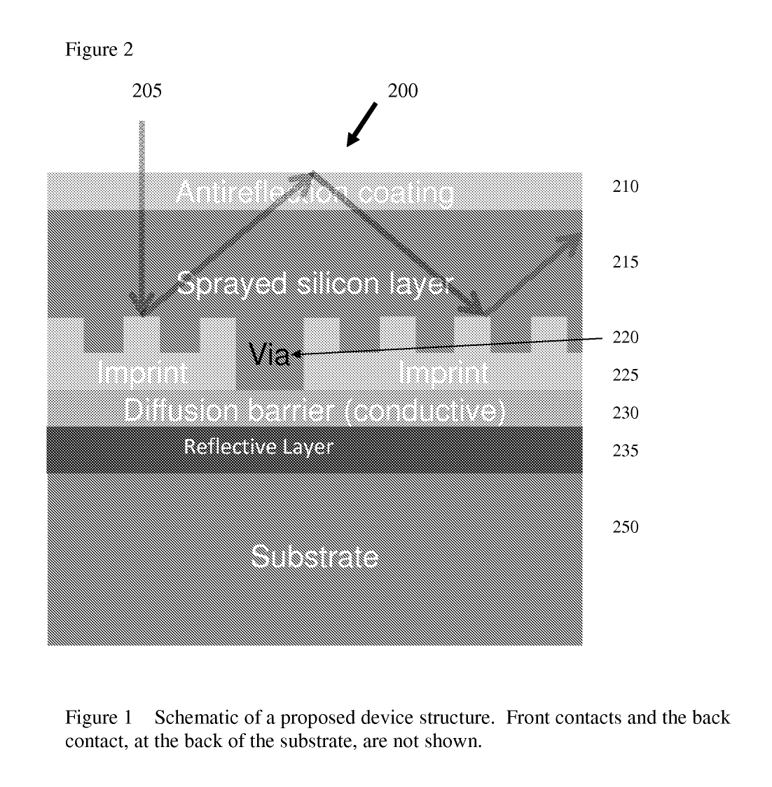

An imprinted layer may be either optically transparent or opaque. In either case, a large optical index mismatch to the index of silicon is required for maximum light reflection. In some embodiments a metal reflector behind an imprint layer provides additional light reflection. An exemplary imprinted layer structure is shown in FIG. 2; light ray 205 enters solar cell structure 200, optionally, through antireflection coating 210, passing through active layer 215 and incident upon imprinted layer 225. Imprinted layer is designed to reflect light ray 205 such that the light ray is captured by total internal reflection based upon thickness and composition of layers 215 and 210 and angles of incidence and reflection. Optional layers in an exemplary structure include a diffusion barrier, 230, reflector layer 235, optionally metallic. Via 220 is filled by active layer 215 composition; via 220 enables electrical continuity between the active layer 215 and the substrate 250 and/or to a conductive layer, optionally 230 and/or 235. Alternative structures are disclosed in U.S. 12/860,048, 12/860,088 and 13/077,870. In some embodiments a via is not needed.

Imprinted layer 225 may be electrically conductive or insulating. In the case of an insulating material, via openings provide electrical conductivity between active layer 215 and a conductive layer or substrate. Optional diffusion barrier 230 and reflector layer 235 are shown in FIG. 2.

Substrate 250 is chosen from a group consisting of graphite, graphite foil, glassy graphite, impregnated graphite, pyrolytic carbon, pyrolytic carbon coated graphite, flexible foil coated with graphite, graphite powder, carbon paper, carbon cloth, carbon, glass, alumina, carbon nanotube coated substrates, carbide coated substrates, graphene coated substrates, silicon-carbon composite, silicon carbide, and mixtures thereof.

A reflective layer 235 is chosen from a group consisting of silicon, SiC, conductive metal nitride, aluminum, copper, silver, transparent metal alloy and transparent conductive metal oxides and combinations thereof. A barrier layer 230 comprises one or more layers of a composition chosen from a group consisting of Si, SiO₂, Al₂O₃, TaN, TiO₂, silicon carbides, silicon nitrides, metal oxides, metal carbides, metal nitrides and conductive ceramics. Active layer 215 is chosen from a group consisting of Group IV, Group III-V and Group II-VI compounds. The various layers are formed by one or more processes chosen from a group consisting of physical vapor deposition, chemical vapor deposition, plasma-enhanced chemical vapor deposition, metal-organic CVD, molecular beam epitaxy, molten liquid application and plasma spraying.

The composition of the imprinted layer is, optionally, a ceramic based material, such as oxides, carbides and nitrides, other ceramics and aluminum oxide phosphate and mixtures thereof. In some embodiments an imprinted layer is thermally stable after curing to withstand a subsequent silicon plasma spray and anneal process. In some embodiments fabrication of an imprinted layer is via sol-gel or related precursors. In some embodiments imprinting of crystalline Boehmite, AlO(OH), sol-gel produces photonic structures for photovoltaic devices. In some embodiments a commercial nanocrystalline Boehmite AlO(OH) sol, Disperal P2, from Sasol is used. Optionally a silicon, graphite and/or Si/C plus ceramic, optionally, plus binder, composite is used for an imprint layer.

A multitude of imprinted patterns can provide the required angle change needed for light trapping. Some embodiments comprise a random surface, such as a Lambertian scatterer. Such random surfaces are used in solar cells, in which a textured front transparent conductive oxide, TCO, optionally an “Asahi U” material, creates light scattering into a silicon layer; alternatively, one, two or three-dimensional diffraction gratings can be imprinted. In some embodiments an interface pattern is located on the surface of the active silicon layer, optionally, a “moth-eye”-type, operable to function as an antireflection coating for a wide range of photovoltaic devices, with periodic and/or aperiodic surface profiles, optionally, with sub-wavelength features; optionally a via is in a surface layer.

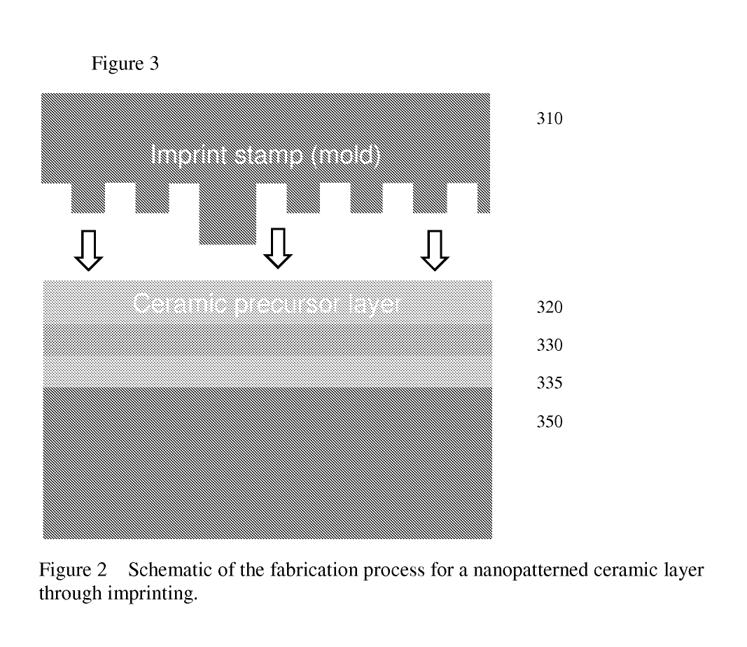

FIG. 3 describes an exemplary imprint process. First, a ceramic precursor layer 320 is applied to a substrate; optionally, the topmost layer on the substrate, such as diffusion barrier 330. Precursor layer 320 may be applied by spin coating, ultrasonic spray deposition, dipping, brushing, screen print or other known technique. Precursor layer is moldable by imprint stamp 310. Precursor layer typically contains an amount of solvent, such as water, alcohol or others such that imprinting is enabled. In some embodiments the layer is imprinted with a reusable mold. A mold is typically a replica of a master mold; in some embodiments a master mold is fabricated by lithography and etching. Reusable molds are fabricated by embossing or casting, using either polymers or epoxy resins; metal molds are also possible, e.g. nickel. After imprinting, a mold is removed and the imprinted layer is cured. Dimensions of a photonic structure imprinted by a mold are typically larger than 20 nm. Dimensions of an imprinted via are larger than 100 nm.

In some embodiments a photovoltaic device comprises a substrate with a conductive layer; an active layer or region operable as a photovoltaic device; and a non-conductive layer separating the substrate with a conductive layer from the active layer; wherein the non-conductive layer comprises an imprinted via in the non-conductive layer such that the active layer is electrically connected to the conductive layer; optionally, the non-conductive layer is imprinted with photonic structures chosen from a group consisting of periodic and aperiodic features; optionally, the non-conductive layer is of a composition chosen from a group consisting of boehmite, Al₂O₃, carbides, nitrides, silicides, other ceramics and mixtures thereof; optionally, the active layer is recrystallized with at least 90% of its grains larger than 10 microns; optionally, larger than 100 microns; optionally, larger than 1 mm; optionally larger than 10 mm.

In some embodiments a method for manufacturing a photovoltaic device comprises the steps; choosing a substrate with a conductive layer; depositing a non-conductive layer; imprinting a structure comprising features into the non-conductive layer; and depositing an active layer operable in the photovoltaic device; wherein the active layer is in electrical contact with the conductive layer through a feature in the imprinted layer; optionally, an additional step of recrystallizing the active layer such that at least 90% of the recrystallized active layer has crystal grains larger than 10 microns in a lateral dimension is added; optionally, larger than 100 microns; optionally, larger than 1 mm; optionally larger than 10 mm, in a lateral dimension; optionally, the additional step of curing the non-conductive layer after the imprinting such that the depositing may be done above 1000° C. is added; optionally, the features are chosen from a group consisting of vias, aperiodic structures and periodic structures.

In some embodiments a photovoltaic device comprises a substrate with a conductive layer; an active layer operable as a photovoltaic device and comprising at least a portion recrystallized such that the recrystallized portion contains grains larger than 10 microns over 90% of the recrystallized portion; and a non-conductive layer separating the substrate with a conductive layer from the active layer; wherein the non-conductive layer comprises an imprinted via in the non-conductive layer such that the active layer is electrically connected to the conductive layer; optionally, comprising at least a portion recrystallized such that the recrystallized portion contains grains larger than 100 microns over 90% of the recrystallized portion; optionally, comprising at least a portion recrystallized such that the recrystallized portion contains grains larger than 1 mm over 90% of the recrystallized portion; optionally, comprising at least a portion recrystallized such that the recrystallized portion contains grains larger than 10 mm over 90% of the recrystallized portion; optionally a photovoltaic device further comprises a second non-conductive layer adjacent the active layer separated from the first non-conductive layer by the active layer wherein the second non-conductive layer comprises features chosen from a group consisting of vias, periodic structures, aperiodic structures, “moth-eye”-type structure and interface patterns.

In the previous description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention.

It will be understood that when a layer is referred to as being “on top of” another layer, it can be directly on the other layer or intervening layers may also be present. In contrast, when a layer is referred to as “contacting” another layer, there are no intervening layers present. Similarly, it will be understood that when a layer is referred to as being “below” another layer, it can be directly under the other layer or intervening layers may also be present.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention. Emodiments described in the application may comprise one or more details, process techniques, parameters or other features of each embodiment mentioned as as well as attributes knowledgeable to one in the art.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defmed herein. All publications, patent applications, patents, and other references mentioned herein are incorporated by reference in their entirety.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

I claim:

1. A photovoltaic device comprising;
a substrate with a conductive layer;
an active layer operable as a photovoltaic device; and
a non-conductive layer separating the substrate with a conductive layer from the active layer; wherein the non-conductive layer comprises an imprinted via in the non-conductive layer such that the active layer is electrically connected to the conductive layer.

2. The photovoltaic device of claim 1 wherein the non-conductive layer is imprinted with photonic structures chosen from a group consisting of periodic and aperiodic features.

3. The photovoltaic device of claim 1 wherein the non-conductive layer is of a composition chosen from a group consisting of boehmite, Al₂O₃, carbides, nitrides, silicides, other ceramics and mixtures thereof.

4. The photovoltaic device of claim 1 wherein the active layer is recrystallized with at least 90% of its grains larger than 10 microns.

5. A method for manufacturing a photovoltaic device comprising the steps;
choosing a substrate with a conductive layer;
depositing a non-conductive layer;
imprinting a structure comprising features into the non-conductive layer; and
depositing an active layer operable in the photovoltaic device; wherein the active layer is in electrical contact with the conductive layer through a feature in the imprinted layer.

6. The method of claim 5 further comprising the step recrystallizing the active layer such that at least 90% of the recrystallized active layer has crystal grains of at least 10 microns in a lateral dimension.

7. The method of claim 5 further comprising the step curing the non-conductive layer after the imprinting such that the depositing may be done above 1000° C.

8. The method of claim 5 wherein the features are chosen from a group consisting of vias, aperiodic structures and periodic structures.

9. A photovoltaic device comprising;
a substrate with a conductive layer;
an active layer operable as a photovoltaic device and comprising at least a portion recrystallized such that the recrystallized portion contains grains larger than 10 microns over 90% of the recrystallized portion; and
a first non-conductive layer separating the substrate with a conductive layer from the active layer; wherein the non-conductive layer comprises an imprinted via in the non-conductive layer such that the active layer is electrically connected to the conductive layer.

10. The photovoltaic device of claim 9 further comprising a second non-conductive layer adjacent the active layer separated from the first non-conductive layer by the active layer wherein the second non-conductive layer comprises features chosen from a group consisting of vias, periodic structures, aperiodic structures, “moth-eye”-type structure and interface patterns.
